(19) United States
(12) Patent Application Publication
(10) Pub. No.: US 2024/0079486 A1
(43) Pub. Date: Mar. 7, 2024

(54) SEMICONDUCTOR STRUCTURE AND METHOD OF MANUFACTURE

(71) Applicant: Taiwan Semiconductor Manufacturing Company Limited, Hsin-Chu (TW)

(72) Inventors: Wei-Ting CHANG, Miaoli County (TW); Ching Yu CHEN, Zhubei (TW); Jiang-He XIE, Hsinchu City (TW)

(21) Appl. No.: 18/126,630

(22) Filed: Mar. 27, 2023

Related U.S. Application Data
(60) Provisional application No. 63/403,918, filed on Sep. 6, 2022.

(51) Int. Cl. H01L 29/778; H01L 21/02; H01L 29/06; H01L 29/20; H01L 29/66; H01L 29/207

(52) U.S. Cl. CPC H01L 29/7786; H01L 21/02104; H01L 21/0254; H01L 21/0262; H01L 29/0684; H01L 29/2003; H01L 29/66462; H01L 21/02378; H01L 21/02381; H01L 21/0242; H01L 21/02433; H01L 21/02458; H01L 21/02505; H01L 29/207

(57) ABSTRACT

A semiconductor structure includes a barrier layer over a channel layer, and a doped layer over the barrier layer. A gate electrode is over the doped layer and a doped interface layer is formed between the barrier layer and the doped layer. The doped interface layer includes a dopant and a metal. The metal has a metal concentration that follows a gradient function from a highest metal concentration to a lowest metal concentration.

### CROSS-REFERENCE TO RELATED APPLICATIONS

This application claims priority to U.S. Patent Application 63/403,918, titled “SEMICONDUCTOR STRUCTURE AND METHOD OF MANUFACTURE” and filed on Sep. 6, 2022, which is incorporated herein by reference.

### BACKGROUND

Semiconductor devices are useful in a multitude of electronic devices, such as mobile phones, laptops, desktops, tablets, watches, gaming systems, and various other industrial, commercial, and consumer electronics. Semiconductor devices may be formed on a semiconductor substrate and may interact with components and/or layers of the semiconductor substrate to form various integrated circuit devices, such as high-power field-effect transistors, high-frequency transistors, high electron mobility transistors (HEMTs), etc. A HEMT is a field effect transistor incorporating a junction between two materials with different band gaps (i.e., a heterojunction) as the channel instead of a doped region, which is generally found in metal oxide semiconductor field effect transistors (MOSFETs). HEMTs, like other field effect transistors (FETs), are useful in integrated circuits as digital switches and as amplifiers for controlling large currents using a small voltage control signal. HEMTs generally have the ability to operate at higher frequencies than MOSFETs, such as microwave frequencies, and are incorporated into high-frequency electronic devices such as cell phones, satellite television receivers, voltage converters, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a semiconductor arrangement, according to some embodiments.

FIG. 2 illustrates a semiconductor arrangement including semiconductor structures and band graphs, according to some embodiments.

FIG. 3 illustrates a semiconductor structure, concentration graph, and layer profile table, according to some embodiments.

FIGS. 4A-4H illustrate a semiconductor structure at various stages of fabrication, according to some embodiments.

FIG. 5 illustrates a method of making a semiconductor structure, according to some embodiments.

### DETAILED DESCRIPTION

The following disclosure provides several different embodiments, or examples, for implementing different features of the provided subject matter with reference to the drawings, wherein like reference numerals are generally used to refer to like elements throughout. In the following description, for purposes of explanation, numerous specific details are set forth in order to provide an understanding of the claimed subject matter. It is evident, however, that the claimed subject matter can be practiced without these specific details. In other instances, structures and devices are illustrated in block diagram form in order to facilitate describing the claimed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly. Also, relationship terms such as “connected to,” “adjacent to,” “coupled to,” and the like, may be used herein to describe both direct and indirect relationships. “Directly” connected, adjacent, or coupled may refer to a relationship in which there are no intervening components, devices, or structures. “Indirectly” connected, adjacent, or coupled may refer to a relationship in which there are intervening components, devices, or structures.

Structures, devices, and/or methods for improving device reliability and/or improving gate control in semiconductor arrangements and/or structures are provided. Power electronics utilize semiconductor devices and/or structures to control and manage electric power (i.e., current, voltage, frequency, etc.) for targeted applications. Silicon (Si) based devices (also known as Si-based devices or simply “silicon”) have been historically dominant for power electronics devices. An example Si-based device is a MOSFET. An increased demand for higher current, higher voltage and/or higher power density, as well as better energy efficiency, presents a need to overcome inherent limitations of Si-based devices. Wide band gap (WBG) semiconductors, such as silicon carbide (4H—SiC) and gallium nitride (GaN), are useful to provide increased energy efficiency in power electronics. Si-based devices may be combined with WBG semiconductors, such as GaN-based enhancement mode HEMT (E-HEMT) devices, to provide useful circuits. For example, a normally-off GaN transistor may be obtained in a “cascode” configuration by combining a high-voltage (e.g., 600 V) normally-on GaN HEMT with a low-voltage (e.g., 30 V) normally-off Si MOSFET.

E-HEMT devices may utilize p-GaN semiconductor structures for gate control. Layer interaction in E-HEMT semiconductor structures, such as interaction between a p-GaN layer, an AlGaN layer, and a GaN layer, may be improved to increase gate control and increase device reliability. During operation, a p-GaN layer may be controlled by a gate (e.g., a gate electrode) to deplete a two-dimensional electron gas (2DEG) in a channel layer of an interface of an AlGaN layer and a GaN layer. The 2DEG is formed due to spontaneous and piezoelectric polarization of a crystalline structure of the E-HEMT and result in normally-off operation. A counter analogue to 2DEG, a two-dimensional electron hole gas (2DHG), may be present at p-type interfaces. The p-GaN layer and the AlGaN layer may interact about the p-GaN/AlGaN interface where 2DHG is present above the fermi level (E_{F}) due to a negative polarization charge. The 2DEG and the 2DHG may have different mobility and different valence bands due to a variety of factors, such as crystalline structure, lattice continuity, polar discontinuity, dangling bonds, etc. The presence of 2DHG above the fermi level (E_{F}) may reduce a threshold voltage of the E-HEMT and limit charge mobility (i.e., enhance trap behavior of electrical charge), which may impact device reliability.

In accordance with some embodiments, a doped interface layer is formed in a semiconductor structure between a barrier layer (e.g., AlGaN) and a doped layer (e.g., p-GaN). The doped interface layer includes a dopant and a metal, where the metal has a metal concentration that follows a gradient function from a highest metal concentration to a lowest metal concentration. In some embodiments, the doped interface layer includes a grading (i.e., linear) concentration of aluminum (Al) in a p-AlGaN layer to reduce and/or effectively eliminate 2DHG above the fermi level (E_{F}) and thereby improve gate control. A linear Al concentration, such as a smooth Al composition about a p-AlGaN/AlGaN interface may present better film quality (e.g., reduce and/or eliminate lattice mismatch), and may reduce the interface trapping center to improve device reliability.

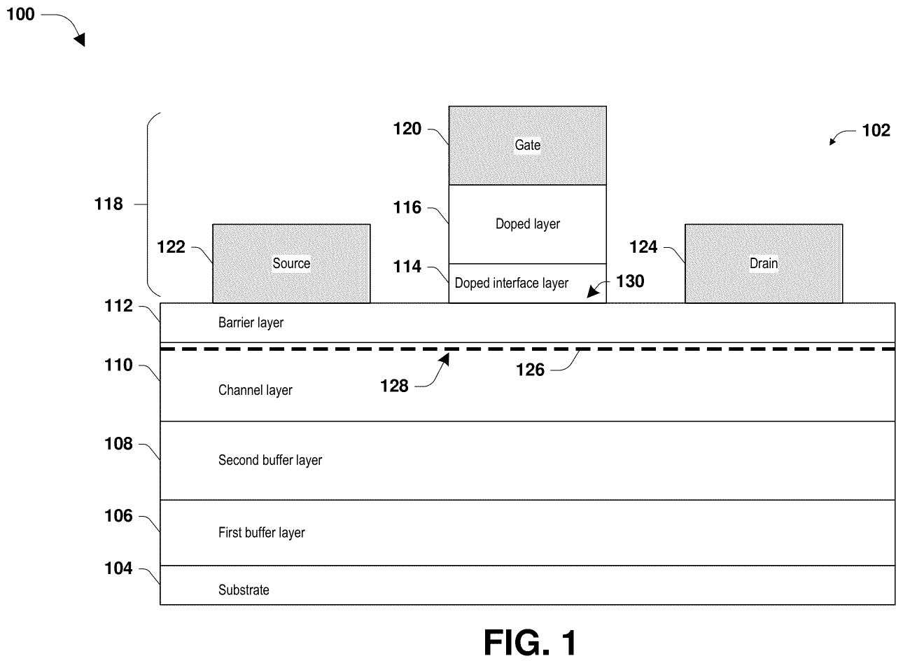

FIG. 1 illustrates a semiconductor arrangement 100, according to some embodiments. FIG. 1 is a cross-sectional view of a semiconductor structure 102. According to some embodiments, the semiconductor structure 102 includes a substrate 104, which may include a doped region such as a p-type region or an n-type region. In some embodiments, the semiconductor structure 102 includes a first buffer layer 106 over the substrate 104, a second buffer layer 108 over the first buffer layer 106, a channel layer 110 over the second buffer layer 108, a barrier layer 112 over the channel layer, a doped interface layer 114 over the barrier layer 112, and a doped layer 116 over the doped interface layer 114. The semiconductor structure 102 may include a transistor structure 118 over the doped interface layer 114. The transistor structure 118 may include a gate electrode 120, a source electrode 122, and a drain electrode 124. In some embodiments, the gate electrode 120 is over the doped layer 116 and the doped interface layer 114. In some embodiments, the transistor structure 118 is a HEMT.

According to some embodiments, the substrate 104 comprises at least one of an epitaxial layer, a silicon-on-insulator (SOI) structure, a wafer, a die formed from a wafer, or other type of structure. For example, the epitaxial layer may comprise a deposition of an overlayer on a crystalline substrate, where the overlayer is in registry with the substrate 104. In some embodiments, SOI substrates are fabricated using separation by implantation of oxygen (SIMOX), wafer bonding, and/or other suitable methods. In some embodiments, the substrate 104 includes an insulator layer (not shown). The insulator layer may be comprised of any suitable material, including silicon oxide, sapphire, other suitable insulating materials, and/or combinations thereof. An exemplary insulator layer may be a buried oxide layer (BOX). The insulator may be formed by any suitable process, such as implantation (e.g., SIMOX), oxidation, deposition, and/or other suitable process. In some embodiments, the epitaxial layer may comprise a type of crystal growth or material deposition in which new crystalline layers are formed with one or more well-defined orientations with respect to a crystalline seed layer of the substrate 104. In some embodiments, the substrate 104 comprises at least one of a silicon carbide (SiC) substrate, a sapphire substrate, a bulk silicon substrate, or a crystal silicon substrate. In some embodiments, the substrate 104 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AllnAs, AlGaAs, GalnAs, GaInP, GalnAsP, other suitable material, or combinations thereof. In some embodiments, the substrate 104 may be comprised of an elementary semiconductor in a crystalline structure, a compound semiconductor in a crystalline structure, or other mixtures in a crystalline structure.

Crystal orientation may be described by a basic unit cell, i.e., a triclinic system, using six independent lattice parameters (three lengths and three angles). For a cubic system, such as a silicon substrate, the unit cell length is the same in all three directions and all angles are 90°. In this direct space, any point within the crystal has all integer coordinates corresponds to a corner lattice point (i.e., vertex) of a unit cell. Crystal orientation may be generally specified by Miller indices, (h, k, l), which correspond to three direct space coordinate axis intercepts. Three points uniquely determine a geometric plane, and three axis intercepts define a crystallographic plane. A plane that intersects each axis at a distance of one lattice parameter from the origin, i.e., the plane has unit intercepts on each coordinate axis, may be identified as the <111> crystallographic plane. A plane that is parallel to the y and z axes, but has unit intercept on the x axis, may designate the Miller indices, h, k, and l as reciprocals of the x, y, and z axis intercepts instead of the intercepts themselves, and may be identified as the <100> crystallographic plane. A plane that is parallel to the z axis, but has unit intercepts on the x and y axes is designated as <110>. Miller indices, <100>, <010>, and <001> denote different families of crystallographic planes with all planes corresponding to a face of the unit cell. Many crystalline structures exhibit a high degree of symmetry, such as a diamond cubic structure. As a consequence of a high degree of symmetry characteristic of a diamond cubic structure, all planes <100>, <010>, and <001> are electrically and structurally equivalent. Any crystallographic plane corresponding to a face of the unit cell may be generically denoted as a “<100>” plane. Any crystallographic plane that “cuts” a unit cell face diagonally and is also parallel to an edge of the unit cell may be denoted as a “<110>” plane. Any crystallographic plane that intersects three non-adjacent vertices of the unit cell may be denoted as a “<111>” plane. In each unit cell, there may be three different (i.e., non-parallel) <100> planes, six different <110> planes, and four different <111> planes.

A silicon crystal substrate, which has a surface parallel to the unit cell face, is designated <100>. Similarly, if the surface can be thought of as intersecting three opposite corners of the unit cell, then the crystal is designated <111>. Silicon crystal <100>, alternately referred to as “Si(100),” may be used for fabrication of CMOS devices. Silicon crystal <111>, alternately referred to as “Si(111),” may be used for fabrication of bipolar devices, such as a HEMT, where a shallow doping is desirable. In some embodiments, CMOS devices and/or bipolar devices may alternately be formed with silicon crystal <100> and/or silicon crystal <111>. In some embodiments, the substrate 104 may include silicon crystal <100> and/or silicon crystal <111> regions. The atomic arrangement for each crystal surface, i.e., <100>, <111>, and <110>, is different, and each may relate to a density of dangling bonds that are left behind if a crystal breaks or “cleaves” parallel to a particular crystallographic plane. This density is directly related to the surface energy of a crystal of a particular orientation. In the diamond cubic structure, for a <100> plane, four bonds per unit cell must be broken in order to cleave the crystal. For cleavage parallel to a <111> plane, only three bonds per unit cell must be broken. A Si(100) substrate structure naturally separates into quarters and a Si(111) substrate structure naturally separates into sixths. In some embodiments, the substrate 104 includes a Si(111) substrate structure that may be more susceptible to damage from ion implantation, e.g., to create a doped region, than a Si(100) substrate structure. In some embodiments, the substrate 104 comprises a Si(111) structure having a resistivity less than 100 Ohm-cm. In some embodiments, the lattice structure of the substrate 104 may be the same type as one or more other lattice structures of layers above the substrate 104 to enhance charge mobility. Other arrangements and/or configurations of the substrate 104 are within the scope of the present disclosure.

According to some embodiments, the first buffer layer 106 is over the substrate 104. In some embodiments, the first buffer layer 106 is in direct contact with the substrate 104. In some embodiments, the first buffer layer 106 is in indirect contact with the substrate 104. For example, another intervening layer, such as an adhesion layer, a lattice protection layer, etc., may be between the first buffer layer 106 and the substrate 104. The first buffer layer 106 may act as a buffer and/or a transition layer for subsequently formed overlying layers.

In some embodiments, the first buffer layer 106 may be epitaxially grown through crystal growth and/or material deposition in which new crystalline layers are formed with one or more well-defined orientations with respect to a crystalline seed layer. The deposited crystalline film may be referred to as epitaxial film or epitaxial layer. The relative orientation of the epitaxial layer to the seed layer may be defined in terms of the orientation of the crystal lattice of each material. In some embodiments, the first buffer layer 106 may be grown through homoepitaxy, also known as “homoepi,” where epitaxy may be performed with only one material. In homoepitaxy, a crystalline film is grown on a substrate or film of the same material. In some embodiments, homoepitaxy may be used to grow a film which is more-pure than the substrate 104 and/or to fabricate layers having different doping levels. In some embodiments, the first buffer layer 106 may be grown through homotopotaxy, where a thin-film growth is not limited to two-dimensional growth and the substrate 104 may be a thin-film material. In some embodiments, the first buffer layer 106 may be grown through heteroepitaxy, using materials that are different from each other. For example, in heteroepitaxy, a crystalline film grows on a crystalline substrate or film of a different material. In some embodiments, crystalline films of materials are grown to fabricate integrated crystalline layers of different materials. Examples of heteroepitaxy may include silicon on sapphire, gallium nitride (GaN) on sapphire, aluminum gallium indium phosphide (AlGaInP) on gallium arsenide (GaAs), diamond, iridium, graphene on hexagonal boron nitride (hBN), or other types of crystalline films. In some embodiments, homoepitaxial growth of the first buffer layer 106 may include chemical or physical vapor deposition methods that deliver the precursors to the substrate in a gaseous state. In some embodiments, the first buffer layer 106 may be formed through vapor-phase epitaxial (VPE) growth, using, for example, silane, dichlorosilane, trichlorosilane, another source gas, and/or a mixture thereof. In some embodiments, the first buffer layer 106 is grown through VPE, such as hydride VPE (HVPE), metal-organic VPE (MOVPE), metal-organic chemical vapor deposition (MOCVD), molecular beam epitaxy (MBE) with radio frequency (RF) nitrogen as a gas source, or another type of VPE growth.

The first buffer layer 106 may function as an interface to reduce lattice mismatch between the substrate 104 and subsequently formed layers. Such lattice mismatch may occur due to damage to the Si(111) crystalline structure of the substrate 104 during formation of, for example, a p-type region and/or an n-type region. In some embodiments, the first buffer layer 106 includes aluminum nitride (AlN) or an AlN layer. In some embodiments, the first buffer layer 106 may include an AlN layer having a thickness in a range between about 10 nanometers (nm) and about 300 nm. In some embodiments, the AlN layer comprises a hexagonal wurtzite crystal structure, a metastable cubic zinc-blende phase, such as in the form of a thin film, or another type of structure. The first buffer layer 106 may include a single layer or a plurality of layers. In a case of multiple layers, the first buffer layer 106 may include a low-temperature AlN layer (not shown) formed at a temperature between about 800 degrees Celsius (° C.) and about 1,200° C., and/or a high-temperature AlN layer (not shown) formed at a temperature between about 1,000° C. and about 1,400° C.

In some embodiments, the first buffer layer 106 includes a III-V compound made from the III-V groups in the periodic table of elements. Group III binary elements include B, Al, Ga, In, or TI. Group III binary elements include N, P, As, Sb, or Bi. In some embodiments, the first buffer layer 106 includes at least one of BN, AlN, GaN, InN, TIN, BP, AlP, GaP, InP, TIP, Bas, AlAs, GaAs, InAs, TIAs, BSb, AlSb, GaSb, InSb, TISb, BBi, AlBi, GaBi, InBi, or TIBi. In some embodiments, the first buffer layer 106 includes at least one of aluminum antimonide, aluminum arsenide, aluminum gallium arsenide, aluminum gallium indium phosphide, aluminum gallium nitride, aluminum gallium phosphide, aluminum indium arsenide, aluminum nitride, aluminum phosphide, boron arsenide, boron nitride, boron phosphide, gallium antimonide, gallium arsenide, gallium arsenide phosphide, gallium indium arsenide antimonide phosphide, gallium phosphide, indium antimonide, indium arsenide, indium arsenide antimonide phosphide, indium gallium arsenide, indium gallium nitride, indium gallium phosphide, indium nitride, indium phosphide, graphene, or nanomesh. In some embodiments, the first buffer layer 106 includes: a III-V compound alone, a III-V compound in combination with another III-V compound, or a III-V compound in combination with another material.

In some embodiments, the first buffer layer 106 includes an aluminum gallium nitride (AlGaN) layer. In some embodiments, aluminum gallium nitride comprises any alloy of aluminum nitride and gallium nitride. In some embodiments, aluminum gallium nitride may be represented as Al_{X}Ga_{1-X}N, where “x” denotes a composition of material and has a value (0≤x≤1). For example, where Al_{X}Ga_{1-X}N has an Al composition of x=0.39 (Al_{0.39}), the Ga composition would be Ga_{1-X}=Ga_{1-0.39}=Ga_{0.61}. In this example, the AlGa group would be 39% Al and 61% Ga. Other compositions of Al and Ga within aluminum gallium nitride are within the scope of the present disclosure. In some embodiments, the bandgap of Al_{X}Ga_{1-X}N is between about 3.4 eV (Al_{X} for x=0) to 6.2 eV (Al_{X} for x=1).

In some embodiments, the first buffer layer 106 includes an aluminum gallium arsenide (AlGaAs) layer. In some embodiments, aluminum gallium arsenide comprises any alloy of aluminum arsenide and gallium arsenide. In some embodiments, aluminum gallium arsenide may be represented as Al_{X}Ga_{1-X}As, as set forth herein. In some embodiments, the bandgap of Al_{X}Ga_{1-X}As is between about 1.42 eV (Al_{X} for x=0) to 6.2 eV (Al_{X} for x=1). In some embodiments, the first buffer layer 106 forms a heterojunction with another layer and/or another III-V compound layer.

In some embodiments, the first buffer layer 106 comprises two layers with different percentages of Al. For example, the first buffer layer 106 may include an AlN layer with a first percentage of Al and an AlGaN layer with a second percentage of Al. Alternatively, the two layers of the first buffer layer 106 may comprise AlGaAs or AlInP with different percentages of Al. In some embodiments, the percentage of Al of one of the two layers of the first buffer layer 106 is lower than the other of the two layers of the first buffer layer 106. In some embodiments, a ratio of the percentage of Al of the one layer of the first buffer layer 106 to that of the other layer of the first buffer layer 106 is in a range from about 1.1 to 2.5. For example, the percentage of Al of AlGaN of the one layer of the first buffer layer 106 may be 16% and the percentage of Al of AlGaN of the other layer of the first buffer layer 106 may be in a range from about 17.6% to 40%. In some embodiments, the percentage of Al of AlGaN of the one layer of the first buffer layer 106 is in a range from about 12% to about 18% while the percentage of Al of AlGaN of the other layer of the first buffer layer 106 is in a range from about 23% to about 40%. In some embodiments, the first buffer layer 106 may have more than two AlGaN layers, each having a different percentage of Al. In some embodiments, the percentage of Al of AlGaN layers increases as the AlGaN layer is distant from the substrate 104. For example, the one layer of the AlGaN layer of the first buffer layer 106 with a higher percentage of Al may be grown on the other layer of the AlGaN layer of the first buffer layer with a lower percentage of Al, which may be grown on the substrate 104. Other compositions and/or configurations of the first buffer layer 106 are within the scope of the present disclosure.

In some embodiments, the first buffer layer 106 is epitaxially grown by using, for example, MOCVD, during which a gallium-containing precursor and/or a nitrogen-containing precursor are used. The gallium-containing precursor may include trimethylgallium (TMG), triethylgallium (TEG), or other suitable gallium-containing chemicals. In some embodiments, the Ga in the first buffer layer 106 is in form of trimethylgallium (TMG), such that the Al in the first buffer layer 106 is in form of trimethylaluminum (TMAI). In some embodiments, Mg in a subsequent layer, such as the doped layer 116, is in form of Bis(cyclopentadienyl)magnesium (Cp2Mg SSG), where SSG denotes Select Semiconductor Grade. In some embodiments, Cp2Mg SSG is applied as dopant. The nitrogen-containing precursor may include ammonia (NH₃), tertiarybutylamine (TBAm), phenyl hydrazine, or other suitable chemicals. In some embodiments, the first buffer layer 106 is undoped. In some embodiments, the first buffer layer 106 is unintentionally doped, such as through integration of a dopant by another stage of fabrication. In some embodiments, the first buffer layer 106 is lightly doped. For example, the doped interface layer 114 may be lightly doped with p-type dopants due to a precursor used to form the doped interface layer 114. In some embodiments, the first buffer layer 106 has a thickness in a range from about 5 nm to about 10 microns (μm). In some embodiments, the first buffer layer 106 has a thickness in a range from about 5 nm to about 50 nm. In some embodiments, the first buffer layer 106 has a thickness in a range from about 0.5 jam to about 10 μm. Other dimensions and/or configurations of the first buffer layer 106 are within the scope of the present disclosure.

According to some embodiments, the second buffer layer 108 is over the first buffer layer 106. In some embodiments, the second buffer layer 108 is in direct contact with the first buffer layer 106. In some embodiments, the second buffer layer 108 is in indirect contact with the first buffer layer 106 or the substrate 104. For example, another intervening layer, such as an adhesion layer, a lattice protection layer, etc., may be between the second buffer layer 108 and the first buffer layer 106. The second buffer layer 108 may act as a second buffer and/or second transition layer for subsequently formed overlying layers.

In some embodiments, the second buffer layer 108 may be epitaxially grown through crystal growth and/or material deposition in which new crystalline layers are formed with one or more well-defined orientations with respect to a crystalline seed layer. The deposited crystalline film may be grown in a manner described herein with respect to the first buffer layer 106. In some embodiments, the second buffer layer 108 may be grown through homoepitaxy, homotopotaxy, heteroepitaxy, or other manner described herein. In some embodiments, the second buffer layer 108 may be formed through VPE growth, using, for example, silane, dichlorosilane, trichlorosilane, another source gas, and/or a mixture thereof. In some embodiments, the second buffer layer 108 is grown through VPE, such as HYPE, MOVPE, MOCVD, MBE, or another type of VPE growth.

The second buffer layer 108 may function as an interface to reduce lattice mismatch between the first buffer layer 106 and/or subsequently formed layers. Such lattice mismatch may occur due crystalline structure damages as set forth in greater detail herein. In some embodiments, the second buffer layer 108 includes GaN doped with at least one of carbon (C—GaN) or iron (Fe—GaN). In some embodiments, GaN doped with at least one of carbon or iron provides deep acceptor doping to improve device breakdown voltage. In some embodiments, the second buffer layer 108 includes a III-V compound made from the III-V groups in the periodic table of elements. For example, the second buffer layer 108 may include one or more Group III binary elements. In some embodiments, the second buffer layer 108 includes at least one of BN, AlN, GaN, InN, TIN, BP, AlP, GaP, InP, TIP, Bas, AlAs, GaAs, InAs, TIAs, BSb, AlSb, GaSb, InSb, TISb, BBi, AlBi, GaBi, InBi, or TIBi. In some embodiments, the second buffer layer 108 includes: a III-V compound alone, a III-V compound in combination with another III-V compound, a III-V compound in combination with another material, or a III-V compound that has been patterned.

In some embodiments, the second buffer layer 108 includes a cubic crystal III-V material, such as a cubic crystal GaN (c-GaN) material. In some embodiments, the second buffer layer 108 includes a hexagonal crystal III-V material, such as a hexagonal crystal GaN (h-GaN) material. In some embodiments, a hexagonal crystal GaN (h-GaN) material is single crystal are grown on a (111) crystal surface and then combined with each other to form cubic crystal GaN (c-GaN) material at a central region of the second buffer layer 108. In some embodiments the c-GaN material includes patterned structures that may be patterned about a portion of the second buffer layer 108. In some embodiments the c-GaN material of the second buffer layer 108 does not include patterned structures. In some embodiments, freestanding c-GaN nanostructures may be produced using a GaN-on-silicon system. For example, nanoscale c-GaN gratings may be realized by fast-atom beam (FAB) etching, and freestanding GaN gratings may be produced by removing an underlying substrate material of the second buffer layer 108 using deep reactive ion etching (DRIE). The freestanding GaN material may be thinned by etching to reduce confined modes of GaN material from the second buffer layer 108. In some embodiments, freestanding c-GaN nanostructures may enhance peak intensity and integrated intensity of carrier movement through subsequently formed layers, such as the channel layer 110. In some embodiments, freestanding c-GaN nanostructures may be formed in the second buffer layer 108 by epitaxial growth of the GaN material over a pattern, also known as a GaN-on-patterned substrate method. In some embodiments, freestanding c-GaN nanostructures may be fabricated through isotropic wet etch techniques or selective photoelectrochemical (PEC) etching. In some embodiments, freestanding c-GaN nanostructures may be fabricated by patterning through removal of an underlying material or an overlying material using a laser lift-off technique. Other configurations and/or techniques for forming the second buffer layer 108 as a c-GaN material are within the scope of the present disclosure.

In some embodiments, the second buffer layer 108 is epitaxially grown by using, for example, MOCVD, during which a gallium-containing precursor and/or a nitrogen-containing precursor are used, as set forth in greater detail herein. In some embodiments, the second buffer layer 108 is undoped. In some embodiments, the second buffer layer 108 is unintentionally doped, such as through integration of a dopant by another stage of fabrication. In some embodiments, the second buffer layer 108 is lightly doped. For example, the substrate 104 or a subsequently formed layer may be lightly doped with p-type dopants due to a precursor, which may lightly dope the second buffer layer 108.

In some embodiments, the second buffer layer 108 has a thickness about the same as the first buffer layer 106, such as in a range from about 5 nm to about 10 microns (μm), in a range from about 5 nm to about 50 nm, in a range from about 0.5 μm to about 10 μm, or another range. In some embodiments, the second buffer layer 108 has a thickness greater than the first buffer layer 106. In some embodiments, the second buffer layer 108 has a thickness less than the first buffer layer 106. Other dimensions and/or configurations of the second buffer layer 108 are within the scope of the present disclosure.

According to some embodiments, the channel layer 110 is over the second buffer layer 108. In some embodiments, the channel layer 110 is in direct contact with the second buffer layer 108. In some embodiments, the channel layer 110 is in indirect contact with the second buffer layer 108, the first buffer layer 106, or the substrate 104. For example, another intervening layer, such as an adhesion layer, a lattice protection layer, etc., may be between the channel layer 110 and the second buffer layer 108. In some embodiments, the channel layer 110 forms a channel 126 of charge carriers to convey a flow of current from the source electrode 122 to the drain electrode 124. The charge carriers may include the 2DEG 128 and/or the 2DHG 130, as an analog to the 2DEG 128, to transport the current from the source electrode 122 to the drain electrode 124. In some embodiments, the 2DEG 128 is located substantially at the interface between the channel layer 110 and the barrier layer 112, with little to none of the 2DHG 130 at the interface between the channel layer 110 and the barrier layer 112. In some embodiments, the 2DHG 130 is located substantially at the interface between the barrier layer 112 and the doped interface layer 114, with little to none of the 2DEG 128 at the interface between the barrier layer 112 and the doped interface layer 114.

In some embodiments, the channel layer 110 may be epitaxially grown through crystal growth and/or material deposition in which new crystalline layers are formed with one or more well-defined orientations with respect to a crystalline seed layer. The deposited crystalline film may be grown in a manner described herein with respect to the first buffer layer 106. In some embodiments, the channel layer 110 may be grown through homoepitaxy, homotopotaxy, heteroepitaxy, or other manner described herein. In some embodiments, the channel layer 110 may be formed through VPE growth, using, for example, silane, dichlorosilane, trichlorosilane, another source gas, and/or a mixture thereof. In some embodiments, the channel layer 110 is grown through VPE, such as HVPE, MOVPE, MOCVD, MBE, or another type of VPE growth.

In some embodiments, the channel layer 110 includes a III-V compound made from the III-V groups in the periodic table of elements. For example, the channel layer 110 may include one or more Group III binary elements. In some embodiments, the channel layer 110 includes at least one of BN, AlN, GaN, InN, TIN, BP, AlP, GaP, InP, TIP, Bas, AlAs, GaAs, InAs, TIAs, BSb, AlSb, GaSb, InSb, TISb, BBi, AlBi, GaBi, InBi, or TIBi. In some embodiments, the channel layer 110 includes: a III-V compound alone, a III-V compound in combination with another III-V compound, or a III-V compound in combination with another material. In some embodiments, the channel layer 110 includes a III-V compound that has been patterned as described herein. In some embodiments, the channel layer 110 includes a III-V compound that has not been patterned.

In some embodiments, the channel layer 110 is epitaxially grown by using, for example, MOCVD, during which a gallium-containing precursor and/or a nitrogen-containing precursor are used. In some embodiments, the channel layer 110 is undoped, such as undoped GaN (u-GaN), where an undoped layer can have relatively better film quality in terms of, for example, material consistency, material uniformity, material homogeneity, etc. In some embodiments, the channel layer 110 is unintentionally doped, such as through integration of a dopant by another stage of fabrication. In some embodiments, the channel layer 110 is lightly doped. For example, the substrate 104 or a subsequently formed layer may be lightly doped with p-type dopants due to a precursor, which may lightly dope the channel layer 110. In some embodiments, an undoped channel layer 110, such as u-GaN, and concomitant quality thereof, promotes the 2DEG 128 being located substantially at the interface between the channel layer 110 and the barrier layer 112, with little to none of the 2DHG 130 being located at the interface between the channel layer 110 and the barrier layer 112.

In some embodiments, the channel layer 110 has a thickness about the same as the first buffer layer 106 or the second buffer layer 108. In some embodiments, the channel layer 110 has a thickness in a range from about 5 nm to about 10 microns (μm), in a range from about 5 nm to about 50 nm, in a range from about 0.5 μm to about 10 μm, or another range. In some embodiments, the channel layer 110 has a thickness greater than the first buffer layer 106 or the second buffer layer 108. In some embodiments, the channel layer 110 has a thickness less than the first buffer layer 106 or the second buffer layer 108. Other dimensions and/or configurations of the channel layer 110 are within the scope of the present disclosure.

According to some embodiments, the barrier layer 112 is over the channel layer 110. In some embodiments, the barrier layer 112 is in direct contact with the channel layer 110. In some embodiments, the barrier layer 112 is in indirect contact with the channel layer 110, the second buffer layer 108, the first buffer layer 106, or the substrate 104. For example, another intervening layer, such as an adhesion layer, a lattice protection layer, etc., may be between the barrier layer 112 and the channel layer 110. The barrier layer 112 has a barrier potential energy for confining the 2DEG 128 and/or the 2DHG 130 in the channel layer 110.

In some embodiments, the barrier layer 112 may be epitaxially grown through crystal growth and/or material deposition in which new crystalline layers are formed with one or more well-defined orientations with respect to a crystalline seed layer. The deposited crystalline film may be grown in a manner described herein with respect to the first buffer layer 106. In some embodiments, the barrier layer 112 may be grown through homoepitaxy, homotopotaxy, heteroepitaxy, or other manner described herein. In some embodiments, the barrier layer 112 may be formed through VPE growth, using, for example, silane, dichlorosilane, trichlorosilane, another source gas, and/or a mixture thereof. In some embodiments, the barrier layer 112 is grown through VPE, such as HVPE, MOVPE, MOCVD, MBE, or another type of VPE growth.

In some embodiments, the barrier layer 112 includes a III-V compound made from the III-V groups in the periodic table of elements. For example, the barrier layer 112 may include one or more Group III binary elements. In some embodiments, the barrier layer 112 includes at least one of BN, AlN, GaN, InN, TIN, BP, AlP, GaP, InP, TIP, Bas, AlAs, AlGaN, GaAs, InAs, TIAs, BSb, AlSb, GaSb, InSb, TISb, BBi, AlBi, GaBi, InBi, or TIBi. In some embodiments, the barrier layer 112 includes at least one of aluminum antimonide, aluminum arsenide, aluminum gallium arsenide, aluminum gallium indium phosphide, aluminum gallium nitride, aluminum gallium phosphide, aluminum indium arsenide, aluminum nitride, aluminum phosphide, boron arsenide, boron nitride, boron phosphide, gallium antimonide, gallium arsenide, gallium arsenide phosphide, gallium indium arsenide antimonide phosphide, gallium phosphide, indium antimonide, indium arsenide, indium arsenide antimonide phosphide, indium gallium arsenide, indium gallium nitride, indium gallium phosphide, indium nitride, indium phosphide, graphene, or nanomesh. In some embodiments, the barrier layer 112 includes: a III-V compound alone, a III-V compound in combination with another III-V compound, or a III-V compound in combination with another material.

In some embodiments, the barrier layer 112 includes an aluminum gallium nitride (AlGaN) layer. In some embodiments, aluminum gallium nitride comprises any alloy of aluminum nitride and gallium nitride. In some embodiments, aluminum gallium nitride may be represented as Al_{X}Ga_{1-X}N, as set forth herein. In some embodiments, the bandgap of Al_{X}Ga_{1-X}N is between about 3.4 eV (Al_{X} for x=0) to 6.2 eV (Al_{X} for x=1).

In some embodiments, the barrier layer 112 includes an aluminum gallium arsenide (AlGaAs) layer. In some embodiments, aluminum gallium arsenide comprises any alloy of aluminum arsenide and gallium arsenide. In some embodiments, aluminum gallium arsenide may be represented as Al_{X}Ga_{1-X}As, as set forth herein. In some embodiments, the bandgap of Al_{X}Ga_{1-X}As is between about 1.42 eV (Al_{X} for x=0) to 6.2 eV (Al_{X} for x=1). In some embodiments, the barrier layer 112 forms a heterojunction with another layer and/or another III-V compound layer.

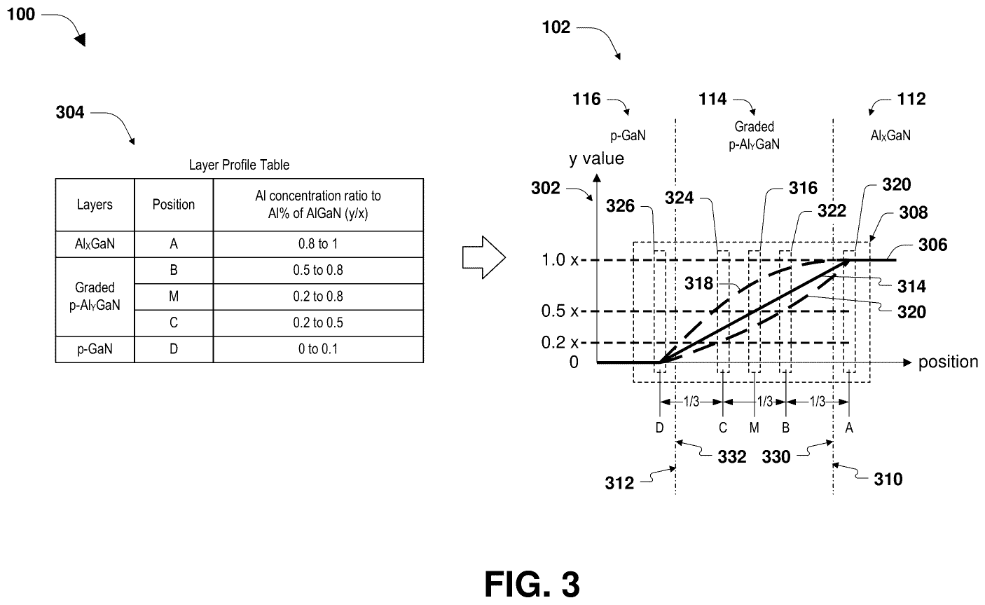

In some embodiments, the barrier layer 112 comprises two or more layers with different percentages of Al. For example, the barrier layer 112 may include a first AlGaN layer with a first percentage of Al and a second AlGaN layer with a second percentage of Al. Alternatively, the two or more layers of the barrier layer 112 may comprise AlGaAs or Al InP with different percentages of Al. In some embodiments, the percentage of Al of one of the two more layers of the barrier layer 112 is lower than another of the two or more layers of the barrier layer 112. In some embodiments, the percentage of Al of one of the two more layers of the barrier layer 112 is greater than another of the two or more layers of the barrier layer 112. In some embodiments, a ratio of the percentage of Al of a subsequently formed layer to the barrier layer 112 or a layer of the barrier layer 112 is in a variable range, as set forth in greater detail with reference to FIG. 3. Other compositions and/or configurations of the barrier layer 112 are within the scope of the present disclosure.

In some embodiments, the barrier layer 112 is epitaxially grown by using, for example, MOCVD, during which a gallium-containing precursor and/or a nitrogen-containing precursor are used. In some embodiments, the barrier layer 112 is undoped. In some embodiments, the barrier layer 112 is unintentionally doped, such as through integration of a dopant by another stage of fabrication. In some embodiments, the barrier layer 112 is lightly doped. For example, the doped interface layer 114 or the doped layer 116 may be lightly doped with p-type dopants due to a precursor, which may lightly dope the barrier layer 112.

In some embodiments, the barrier layer 112 has a thickness about the same as the channel layer 110, the second buffer layer 108, or the first buffer layer 106. In some embodiments, the barrier layer 112 has a thickness in a range from about 5 nm to about 10 microns (μm), in a range from about 5 nm to about 50 nm, in a range from about 0.5 μm to about 10 μm, or another range. In some embodiments, the barrier layer 112 has a thickness greater than the channel layer 110, the second buffer layer 108, or the first buffer layer 106. In some embodiments, the barrier layer 112 has a thickness less than the channel layer 110, the second buffer layer 108, or the first buffer layer 106. Other dimensions and/or configurations of the barrier layer 112 are within the scope of the present disclosure.

According to some embodiments, the doped interface layer 114 is over the barrier layer 112. In some embodiments, the doped interface layer 114 is in direct contact with the barrier layer 112. In some embodiments, the doped interface layer 114 is in indirect contact with the barrier layer 112, the channel layer 110, the second buffer layer 108, the first buffer layer 106, or the substrate 104. For example, another intervening layer, such as an adhesion layer, a lattice protection layer, etc., may be between the doped interface layer 114 and the barrier layer 112. The doped interface layer 114 has a barrier potential energy for confining the 2DEG 128 and/or the 2DHG 130 in the channel layer 110.

In some embodiments, the doped interface layer 114 may be epitaxially grown through crystal growth and/or material deposition in which new crystalline layers are formed with one or more well-defined orientations with respect to a crystalline seed layer. The deposited crystalline film may be grown in a manner described herein with respect to the first buffer layer 106. In some embodiments, the doped interface layer 114 may be grown through homoepitaxy, homotopotaxy, heteroepitaxy, or other manner described herein. In some embodiments, the doped interface layer 114 may be formed through VPE growth, using, for example, silane, dichlorosilane, trichlorosilane, another source gas, and/or a mixture thereof. In some embodiments, the doped interface layer 114 is grown through VPE, such as HYPE, MOVPE, MOCVD, MBE, or another type of VPE growth.

In some embodiments, the doped interface layer 114 includes a III-V compound made from the III-V groups in the periodic table of elements, as set forth in greater detail herein. For example, the doped interface layer 114 may include one or more Group III binary elements. In some embodiments, the doped interface layer 114 includes at least one of BN, AlN, GaN, InN, TIN, BP, AlP, GaP, InP, TIP, Bas, AlAs, GaAs, InAs, TIAs, BSb, AlSb, GaSb, InSb, TISb, BBi, AlBi, GaBi, InBi, or TIBi. In some embodiments, the doped interface layer 114 includes at least one of aluminum antimonide, aluminum arsenide, aluminum gallium arsenide, aluminum gallium indium phosphide, aluminum gallium nitride, aluminum gallium phosphide, aluminum indium arsenide, aluminum nitride, aluminum phosphide, boron arsenide, boron nitride, boron phosphide, gallium antimonide, gallium arsenide, gallium arsenide phosphide, gallium indium arsenide antimonide phosphide, gallium phosphide, indium antimonide, indium arsenide, indium arsenide antimonide phosphide, indium gallium arsenide, indium gallium nitride, indium gallium phosphide, indium nitride, indium phosphide, graphene, or nanomesh. In some embodiments, the doped interface layer 114 includes: a III-V compound alone, a III-V compound in combination with another III-V compound, or a III-V compound in combination with another material.

In some embodiments, the doped interface layer 114 includes an aluminum gallium nitride (AlGaN) layer. In some embodiments, aluminum gallium nitride comprises any alloy of aluminum nitride and gallium nitride. In some embodiments, aluminum gallium nitride may be represented as Al_{X}Ga_{1-X}N, as set forth herein. In some embodiments, the bandgap of Al_{X}Ga_{1-X}N is between about 3.4 eV (Al_{X} for x=0) to 6.2 eV (Al_{X} for x=1).

In some embodiments, the doped interface layer 114 includes an aluminum gallium arsenide (AlGaAs) layer. In some embodiments, aluminum gallium arsenide comprises any alloy of aluminum arsenide and gallium arsenide. In some embodiments, aluminum gallium arsenide may be represented as Al_{X}Ga_{1-X}As, as set forth herein. In some embodiments, the doped interface layer 114 comprises two or more layers with different percentages of Al, two or more portions with different percentages of Al, or a single layer layers with graded percentages of Al. In some embodiments, the percentage of Al in the doped interface layer 114 is a ratio of the percentage of Al in another layer of the semiconductor structure 102, as set forth in greater detail with reference to FIG. 3. For example, the doped interface layer 114 may include a first portion of an AlGaN layer with a first percentage of Al and a second portion of the AlGaN layer with a second percentage of Al, etc. Other compositions and/or configurations of Al in the doped interface layer 114 are within the scope of the present disclosure.

In some embodiments, the doped interface layer 114 is doped with a dopant. The dopant, also known as a doping agent, is a trace impurity, such as an element, that is introduced into a chemical material to alter electrical and/or optical properties. When doped into crystalline base materials, such as silicon in the doped interface layer 114, atoms of the dopant are incorporated into the crystalline base material. The amount of dopant necessary to cause changes is typically low compared to the amount of crystalline base material. The addition of a dopant to a semiconductor, also known as doping, may shift Fermi levels within the base material, resulting in predominantly negative (n-type) or positive (p-type) charge carriers. In some embodiments, the doped interface layer 114 is introduced with a p-type dopant through a solid source technique, a gaseous technique, a spin on liquid technique, and ion implantation technique, or another type of technique. In some embodiments, the doped interface layer 114 is doped with a p-type dopant such as carbon (C), iron (Fe), magnesium (Mg), zinc (Zn), boron (B), gallium (Ga), or other element, compound, or material that creates electron holes as majority charge carriers.

In some embodiments, the doped interface layer 114 is doped with a p-type dopant in the same percentage as another doped layer. For example, the doped interface layer 114 may be doped with a p-type dopant in the same percentage as a p-type dopant of the doped layer 116. In some embodiments, the doped interface layer 114 is doped with a dopant in a greater percentage than another doped layer. In some embodiments, the doped interface layer 114 is doped with a dopant in a less percentage than another doped layer. In some embodiments, the doped interface layer 114 is unintentionally doped with a second dopant, such as through integration of the second dopant by another stage of fabrication. In some embodiments, the doped interface layer 114 is lightly doped. For example, the doped interface layer 114 or the doped layer 116 may be lightly doped with p-type dopants due to a precursor, which may lightly dope the doped interface layer 114.

In some embodiments, the doped interface layer 114 has a thickness about the same as the barrier layer 112, the channel layer 110, the second buffer layer 108, or the first buffer layer 106. In some embodiments, the doped interface layer 114 has a thickness in a range from about 5 nm to about 10 microns (μm), in a range from about 5 nm to about 50 nm, in a range from about 0.5 μm to about 10 μm, or another range. In some embodiments, the doped interface layer 114 has a thickness greater than the barrier layer 112, the channel layer 110, the second buffer layer 108, or the first buffer layer 106. In some embodiments, the doped interface layer 114 has a thickness greater than the barrier layer 112, the channel layer 110, the second buffer layer 108, or the first buffer layer 106. Other dimensions and/or configurations of the doped interface layer 114 are within the scope of the present disclosure.

According to some embodiments, the doped layer 116 is over the doped interface layer 114. In some embodiments, the doped layer 116 is in direct contact with the doped interface layer 114. In some embodiments, the doped layer 116 is in indirect contact with the doped interface layer 114, the barrier layer 112, the channel layer 110, the second buffer layer 108, the first buffer layer 106, or the substrate 104. For example, another intervening layer, such as an adhesion layer, a lattice protection layer, etc., may be between the doped layer 116 and the doped interface layer 114. In some embodiments, the doped layer 116 is configured for depleting the 2DEG 128 under the gate electrode 144 at zero bias. In some embodiments, the doped layer 116 is configured for controlling charge carriers under the gate electrode 120 to control a flow of current from the source electrode 122 to the drain electrode 124. The charge carriers may include a 2DEG 128 and/or a 2DHG, as an analog to the 2DEG 130, to transport the current from the source electrode 122 to the drain electrode 124.

In some embodiments, the doped layer 116 may be epitaxially grown through crystal growth and/or material deposition in which new crystalline layers are formed with one or more well-defined orientations with respect to a crystalline seed layer. The deposited crystalline film may be grown in a manner described herein with respect to the first buffer layer 106. In some embodiments, the doped layer 116 may be grown through homoepitaxy, homotopotaxy, heteroepitaxy, or other manner described herein. In some embodiments, the doped layer 116 may be formed through VPE growth, using, for example, silane, dichlorosilane, trichlorosilane, another source gas, and/or a mixture thereof. In some embodiments, the doped layer 116 is grown through VPE, such as HVPE, MOVPE, MOCVD, MBE, or another type of VPE growth.

In some embodiments, the doped layer 116 includes a III-V compound made from the III-V groups in the periodic table of elements, as set forth herein. For example, the doped layer 116 may include one or more Group III binary elements. In some embodiments, the doped layer 116 includes at least one of BN, AlN, GaN, InN, TIN, BP, AIP, GaP, InP, TIP, Bas, AlAs, GaAs, InAs, TIAs, BSb, AlSb, GaSb, InSb, TISb, BBi, AlBi, GaBi, InBi, or TIBi. In some embodiments, the doped layer 116 includes: a III-V compound alone, a III-V compound in combination with another III-V compound, or a III-V compound in combination with another material.

In some embodiments, the doped layer 116 is doped with a dopant, as set forth herein. In some embodiments, the doped layer 116 is introduced with a p-type dopant through a solid source technique, a gaseous technique, a spin on liquid technique, and ion implantation technique, or another type of technique. In some embodiments, the doped layer 116 is doped with a p-type dopant such as carbon (C), iron (Fe), magnesium (Mg), zinc (Zn), boron (B), gallium (Ga), or other element, compound, or material that creates electron holes as majority charge carriers.

In some embodiments, the doped layer 116 is doped with a p-type dopant in the same percentage as another doped layer. For example, the doped layer 116 may be doped with a p-type dopant in the same percentage as a p-type dopant of the doped interface layer 114. In some embodiments, the doped layer 116 is doped with a dopant in a greater percentage than another doped layer. In some embodiments, the doped layer 116 is doped with a dopant in a less percentage than another doped layer. In some embodiments, the doped layer 116 is unintentionally doped with a second dopant such as through integration of the second dopant by another stage of fabrication. In some embodiments, the doped layer 116 is lightly doped. For example, the doped layer 116 or the doped interface layer 114 may be lightly doped with p-type dopants due to a precursor, which may lightly dope the doped layer 116.

In some embodiments, the doped layer 116 has a thickness about the same as the barrier layer 112, the channel layer 110, the second buffer layer 108, or the first buffer layer 106. In some embodiments, the doped layer 116 has a thickness in a range from about 5 nm to about 10 microns (μm), in a range from about 5 nm to about 50 nm, in a range from about 0.5 μm to about 10 μm, or another range. In some embodiments, the doped layer 116 has a thickness greater than the barrier layer 112, the channel layer 110, the second buffer layer 108, or the first buffer layer 106. In some embodiments, the doped layer 116 has a thickness greater than the barrier layer 112, the channel layer 110, the second buffer layer 108, or the first buffer layer 106. Other dimensions and/or configurations of the doped layer 116 are within the scope of the present disclosure.

According to some embodiments, the gate electrode 120 is over the doped layer 116, the source electrode 122 is over the barrier layer 112, and the drain electrode 124 is over the barrier layer 112. The source electrode 122 is configured for supplying an input current to the 2DEG 128 and/or the 2DHG 130 in the channel layer 110. The drain electrode 124 is configured for supplying an output current from the 2DEG 128 and/or the 2DHG 130 in the channel layer 110. The gate electrode 120 is configured for controlling the input current of the source electrode 122 through the 2DEG 128 and/or the 2DHG 130 to the drain electrode 124, which supplies the output current. In other words, the input current flows from the source electrode 122, through the 2DEG 128 and/or the 2DHG 130, to the drain electrode 124 to produce the output current for the transistor structure 118.

In some embodiments, the gate electrode 120 is in direct contact with the doped layer 116. In some embodiments, the gate electrode 120 is in indirect contact with the doped layer 116, the doped interface layer 114, the barrier layer 112, the channel layer 110, the second buffer layer 108, the first buffer layer 106, or the substrate 104. For example, another intervening layer, such as an adhesion layer, a lattice protection layer, etc., may be between the gate electrode 120 and the doped layer 116. In some embodiments, the source electrode 122 is in direct contact with the doped interface layer 114. In some embodiments, the source electrode 122 is in indirect contact with the doped interface layer 114, the barrier layer 112, the channel layer 110, the second buffer layer 108, the first buffer layer 106, or the substrate 104. For example, another intervening layer, such as an adhesion layer, a lattice protection layer, etc., may be between the source electrode 122 and the doped interface layer 114. In some embodiments, the drain electrode 124 is in direct contact with the doped interface layer 114. In some embodiments, the drain electrode 124 is in indirect contact with the doped interface layer 114, the barrier layer 112, the channel layer 110, the second buffer layer 108, the first buffer layer 106, or the substrate 104. For example, another intervening layer, such as an adhesion layer, a lattice protection layer, etc., may be between the drain electrode 124 and the doped interface layer 114. Other arrangements and/or configurations of the gate electrode 120, the source electrode 122, or the drain electrode 124 are within the scope of the present disclosure.

According to some embodiments, the semiconductor structure 102 includes the barrier layer 112 over the channel layer 110 and the doped layer 116 over the barrier layer 112, with the gate electrode 120 over the doped layer 116. The doped interface layer 114 is formed between the barrier layer 112 and the doped layer 116. The doped interface layer 114 includes a dopant and a metal having a metal concentration that follows a gradient function from a highest metal concentration to a lowest metal concentration. In some embodiments, the metal of the doped interface layer 114 includes aluminum and the metal concentration of the doped interface layer includes an aluminum concentration. In some embodiments, the barrier layer 112 includes the metal having a barrier metal concentration and the gradient function is a ratio of the metal concentration to the barrier metal concentration.

In some embodiments, the semiconductor structure 102 is configured such that the doped layer 116 is doped with a p-type dopant, the doped interface layer 114 is doped with the p-type dopant, and the barrier layer 112 is not doped with the p-type dopant. In some embodiments, the channel layer 110 includes a III-V compound, such as a first III-V compound, the barrier layer 112 includes a III-V compound, such as a second III-V compound, the doped interface layer 114 includes a III-V compound, such as a third III-V compound and a dopant, and the doped layer 116 includes a III-V compound, such as a fourth III-V compound and the dopant. For example, the channel layer 110 may include un-doped gallium nitride (GaN), the barrier layer 112 comprises may include aluminum gallium nitride (AlGaN), the doped interface layer 114 may include p-type AlGaN and a dopant, and the doped layer 116 may include the p-type GaN and the dopant. In some embodiments, the doped interface layer 114 includes a metal concentration that follows a gradient function wherein the gradient function is a ratio of aluminum in the AlGaN of the doped interface layer 114 to aluminum in the AlGaN of the barrier layer 112.

In some embodiments, the semiconductor structure 102 includes the doped layer 116 that has a doped potential energy for containing the two-dimensional electron hole gas (2DHG 130), and the doped interface layer 114 that has an interface potential energy for confining the 2DHG 130 in the doped layer 116. The source electrode 122 may be configured for supplying an input current to the 2DHG 130 and the drain electrode 1214 may be configured for supplying an output current. The input current flows from the source electrode 122, through the 2DHG 130, to the drain electrode 124 to produce the output current, wherein the gate electrode 120 is configured for controlling the flow of the input current through the 2DHG 130.

In some embodiments, the semiconductor structure 102 forms a high electron mobility transistor (HEMT), such as the transistor structure 118. The HEMT includes the barrier layer 112 over the channel layer 110, and the doped layer 116, over the barrier layer 112, having a doped potential energy for containing a two-dimensional electron hole gas (2DHG). The HEMT includes the doped interface layer 114, formed between the barrier layer 112 and the doped layer 116, including a metal having a metal concentration to match a metal concentration of the barrier layer 112 and a metal concentration of the doped layer 116. The HEMT includes the doped interface layer 114 having an interface potential energy for confining the 2DHG in the doped layer. The HEMT includes the gate electrode 120 over the doped layer 116 and configured for controlling a flow of input current through the 2DHG, the source electrode 122 configured for supplying an input current to the 2DHG, and the drain electrode 124 configured for supplying an output current, wherein the input current flows from the source electrode, through the 2DHG, to the drain electrode to produce the output current. Other arrangements and/or configurations of the semiconductor structure 102 are within the scope of the present disclosure.

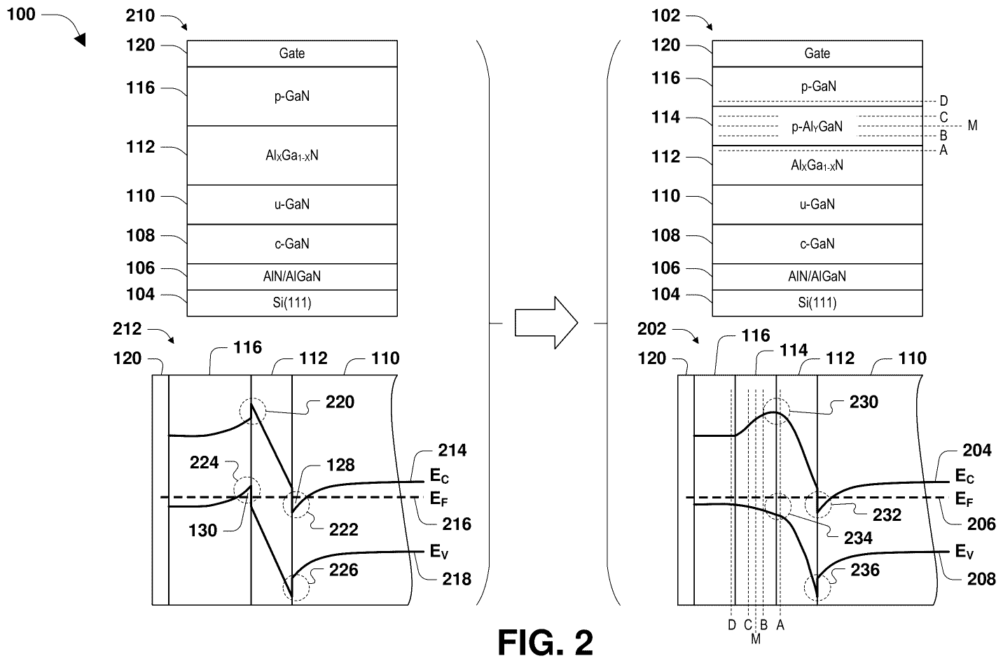

FIG. 2 illustrates the semiconductor arrangement 100 including semiconductor structures and band graphs, according to some embodiments. The semiconductor structure 102 of FIG. 1 has a band graph 202 illustrating a conduction band (E_{C}) 204, a Fermi level (E_{F}) 206, and a valence band (E_{V}) 208 of the semiconductor structure 102, which includes the doped interface layer 114. A second semiconductor structure 210 has a second band graph 212 illustrating a second conduction band (E_{C}) 214, a second Fermi level (E_{F}) 216, and a second valence band (E_{V}) 218 of the second semiconductor structure 210, which does not include the doped interface layer 114. FIG. 2 illustrates an embodiment where the first buffer layer 106 comprises AlN/AlGaN, the second buffer layer 108 comprises c-GaN, the channel layer 110 comprises u-GaN, the barrier layer 112 comprises Al_{X}Ga_{1-X}N, the doped interface layer 114 comprises Al_{Y}GaN, and the doped layer comprises p-GaN, as set forth in greater detail herein.

As illustrated in the second band graph 212 of FIG. 2, the second conduction band (E_{C}) 214 exhibits an upward spike about a first portion 220 of the second conduction band (E_{C}) 214 at an interface of the barrier layer 112 and the doped layer 116. The second conduction band (E_{C}) 214 exhibits a downward spike about a second portion 222 of the second conduction band (E_{C}) 214 at an interface of the channel layer 110 and the barrier layer 112. The second valence band (E_{V}) 218 exhibits an upward spike about a first portion 224 of the second valence band (E_{V}) 218 at an interface of the doped layer 116 and the barrier layer 112. The second valence band (E_{V}) 218 exhibits a downward spike about a second portion 226 of the second valence band (E_{V}) 218 at an interface of the channel layer 110 and the barrier layer 112. As illustrated in the second band graph 212, the first portion 224 of the second valence band (E_{V}) 218 rises above the second Fermi level (E_{F}) 216 and restricts mobility of the 2DHG 130. The second portion 222 of the second conduction band (E_{C}) 214 falls below the second Fermi level (E_{F}) 216.

As illustrated in the semiconductor structure 102 and the band graph 202 of FIG. 2, the doped interface layer 114 is between the barrier layer 112 and the doped layer 116. The doped interface layer 114 comprise a metal, such as Al, having a metal concentration, such as an Al concentration, that follows a gradient function from a highest metal concentration to a lowest metal concentration. In some embodiments, the gradient function is a ratio of the metal concentration of the doped interface layer 114 to the barrier metal concentration of the barrier layer 112. In some embodiments, the metal concentration of the doped interface layer 114 is formed as a metal concentration matrix, described in greater detail herein, that extends into a top portion of the barrier layer 112 and a bottom portion of the doped layer 116, where at least some of the metal concentration matrix has the ratio of the metal concentration of the doped interface layer 114 to the barrier metal concentration of the barrier layer 112. In some embodiments, the metal concentration of the doped interface layer 114 is between about 0 and 5 percent of the atoms of the doped interface layer 114. In some embodiments, the barrier metal concentration of the barrier layer 112 is between about 10 and 30 percent of the atoms of the barrier layer 112.

As illustrated in the semiconductor structure 102 and the band graph 202 of FIG. 2, the metal concentration matrix of the doped interface layer 114 has a varied metal concentration. In some embodiments, a position A of the metal concentration matrix is in the barrier layer 112 below the doped interface layer 114, a position D of the metal concentration matrix is in the doped layer 116 above the position A of the metal concentration matrix, a position M of the metal concentration matrix is in the doped interface layer 114 at a midpoint between position A and position D, a position B of the metal concentration matrix is in the doped interface layer 114 above the position A by about ⅓ of the distance between position A and position D, and a position C of the metal concentration matrix is in the doped interface layer 114 below the position D by about ⅓ of the distance between position A and position D.

As illustrated in the second band graph 212 and the band graph 202 of FIG. 2, the gradient function of the metal concentration of the metal in the doped interface layer 114 changes the conduction bands and the valence bands of the semiconductor structures. As illustrated in the band graph 202 of FIG. 2, the conduction band (E_{C}) 204 exhibits a curvilinear transition about a first portion 230 of the conduction band (E_{C}) 204 at an interface of the barrier layer 112 and the doped interface layer 114. The conduction band (E_{C}) 204 exhibits a downward spike about a second portion 232 of the conduction band (E_{C}) 204 at an interface of the channel layer 110 and the barrier layer 112. The valence band (E_{V}) 208 exhibits a curvilinear transition about a first portion 234 of the valence band (E_{V}) 208 at an interface of the doped interface layer 114 and the barrier layer 112. The valence band (E_{V}) 208 exhibits a downward spike about a second portion 236 of the second valence band (E_{V}) 218 at an interface of the barrier layer 112 and the channel layer 110.

As illustrated in the band graph 202, the first portion 230 of the conduction band (E_{C}) 204 is curvilinear to promote mobility of the 2DEG 130 and enhance flow of current from the source electrode 122 to the drain electrode 124. The first portion 234 of the valence band (E_{V}) 208 is curvilinear and below the Fermi level (E_{F}) 206 to promote mobility of the 2DHG 130 and enhance flow of current from the source electrode 122 to the drain electrode 124. Other arrangements and/or configurations of the semiconductor structures and band graphs are within the scope of the present disclosure.

FIG. 3 illustrates the semiconductor structure 102, a concentration graph 302, and a layer profile table 304, according to some embodiments. In some embodiments, the concentration graph 302 illustrates the doped interface layer 114 where a metal, such as aluminum, has a metal concentration that follows a gradient function 306 from a highest metal concentration to a lowest metal concentration. The metal of the doped interface layer 114 is formed as a metal concentration matrix 308. In some embodiments, the metal concentration matrix 308 is within the doped interface layer 114. In some embodiments, the metal concentration matrix 308 extends into the barrier layer 112 and the doped layer 116.

In some embodiments, the gradient function 306 of the metal concentration of the doped interface layer 114 is linear from a top surface 310 of the barrier layer 112 to a bottom surface 312 of the doped layer 116. As illustrated in FIG. 3, a linear portion 314 of the gradient function 306 extends from the top surface 310 of the barrier layer 112 to the bottom surface 312 of the doped layer 116.

In some embodiments, the gradient function 306 of the metal concentration of the doped interface layer 114 is curvilinear from the top surface 310 of the barrier layer 112 to the bottom surface 312 of the doped layer 116 such that a middle portion 316 of the doped interface layer 114 has a middle portion metal concentration that is greater than half of a sum of a highest metal concentration and a lowest metal concentration. As illustrated in FIG. 3, a first curvilinear portion 318 of the gradient function 306 extends from the top surface 310 of the barrier layer 112 to the bottom surface 312 of the doped layer 116 above the linear portion 314 of the gradient function 306.

In some embodiments, the gradient function 306 of the metal concentration of the doped interface layer 114 is curvilinear from the top surface 310 of the barrier layer 112 to the bottom surface 312 of the doped layer 116 such that the middle portion 316 of the doped interface layer 114 has a middle portion metal concentration that is less than half of a sum of a highest metal concentration and a lowest metal concentration. As illustrated in FIG. 3, a second curvilinear portion 319 of the gradient function 306 extends from the top surface 310 of the barrier layer 112 to the bottom surface 312 of the doped layer 116 below the linear portion 314 of the gradient function 306.

According to some embodiments, the concentration graph 302 illustrates a concentration of Al in the doped interface layer 114. The gradient function 306 is expressed a ratio of a metal concentration of the doped interface layer 114 to a metal concentration of the barrier layer 112. The barrier layer 112 may include Al_{X}GaN, where “x” denotes a composition of Al in Al_{X}GaN, and the doped interface layer 114 may include p-Al_{Y}GaN where “y” denotes a composition of Al in Al_{Y}GaN. The vertical axis of the concentration graph 302 denotes the concentration y (composition of Al in Al_{Y}GaN) as a function of x (composition of Al in Al_{X}GaN). The horizontal axis of the concentration graph 302 denotes positions across the doped interface layer 114. The layer profile table 304 illustrates an Al concentration ratio to Al % of AlGaN (y/x) for the positions across the doped interface layer 114.

As illustrated in the concentration graph 302, a first portion 320 of the metal concentration matrix 308 extends into a top portion of the barrier layer 112 and has the Al concentration ratio (y/x) of between 0.8 and 1. In some embodiments, the first portion 320 of the metal concentration matrix 308 is the same as the top portion of the barrier layer 112. A second portion 322 of the metal concentration matrix 308 is above the first portion 320 and has the Al concentration ratio (y/x) of between 0.5 and 0.8. A third portion 324 of the metal concentration matrix 308 is above the second portion 322 and has the Al concentration ratio (y/x) of between 0.2 and 0.5. A fourth portion 326 of the metal concentration matrix 308 is above the third portion 324, extends into a bottom portion of the doped layer 116, and has the Al concentration ratio (y/x) of between 0.0 and 0.1. In some embodiments, the fourth portion 326 of the metal concentration matrix 308 is the same as the bottom portion of the doped layer 116. In some embodiments, the middle portion 316 of the doped interface layer 114 is a middle portion of the metal concentration matrix 308, and has the Al concentration ratio (y/x) of between 0.2 and 0.8.

In some embodiments, the first portion 320 of the metal concentration matrix 308 is at position A of the metal concentration matrix 308, and position A is 5±5 nm below an interface 330 of the doped interface layer 114 and the barrier layer 112. In some embodiments, position A has an Al concentration ratio (y/x) of 0.9±0.1. In some embodiments, the second portion 322 of the metal concentration matrix 308 is at position B of the metal concentration matrix 308, and position B is about ⅓ *(total thickness of the doped interface layer 114) from position A. In some embodiments, position B has an Al concentration ratio (y/x) of 0.65±0.15. In some embodiments, the third portion 324 of the metal concentration matrix 308 is at position C of the metal concentration matrix 308, and position C is about ⅔ *(total thickness of the doped interface layer 114) from position A. In some embodiments, position C has an Al concentration ratio (y/x) of 0.35±0.15. In some embodiments, the fourth portion 326 of the metal concentration matrix 308 is at position D of the metal concentration matrix 308, and position D is 5±5 nm above an interface 332 of the doped interface layer 114 and the doped layer 116. In some embodiments, position D has an Al concentration ratio (y/x) of 0.5±0.5. Other gradient functions and/or metal concentrations of the doped interface layer 114 are within the scope of the present disclosure.

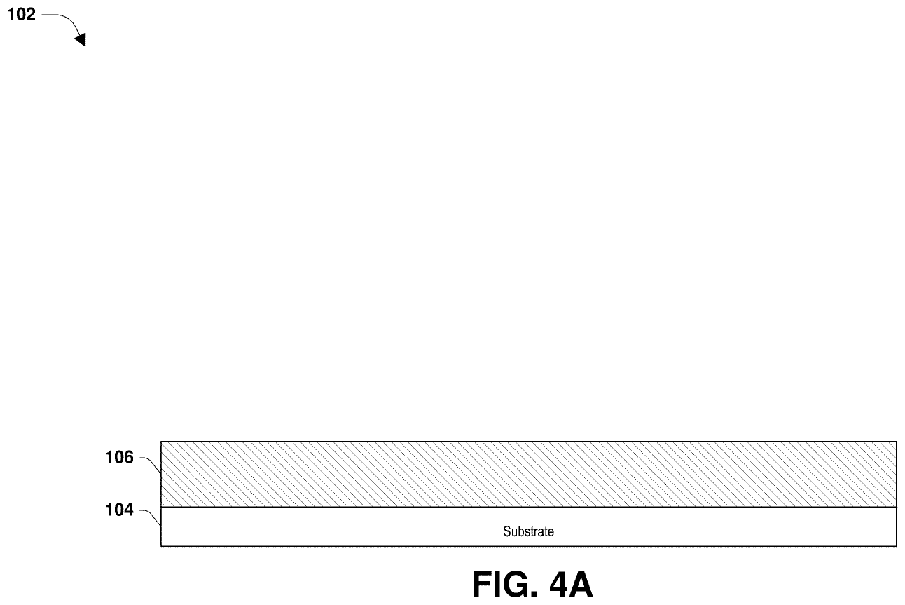

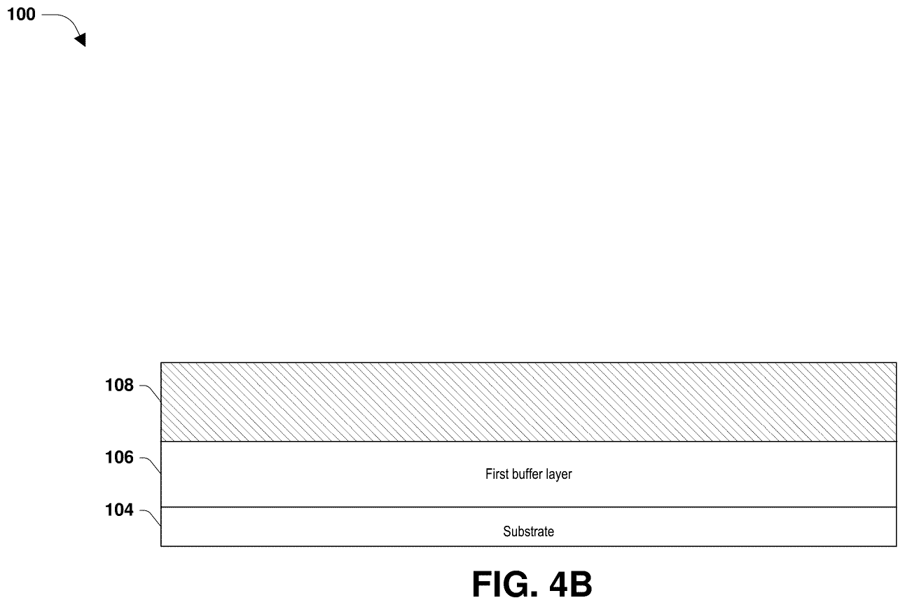

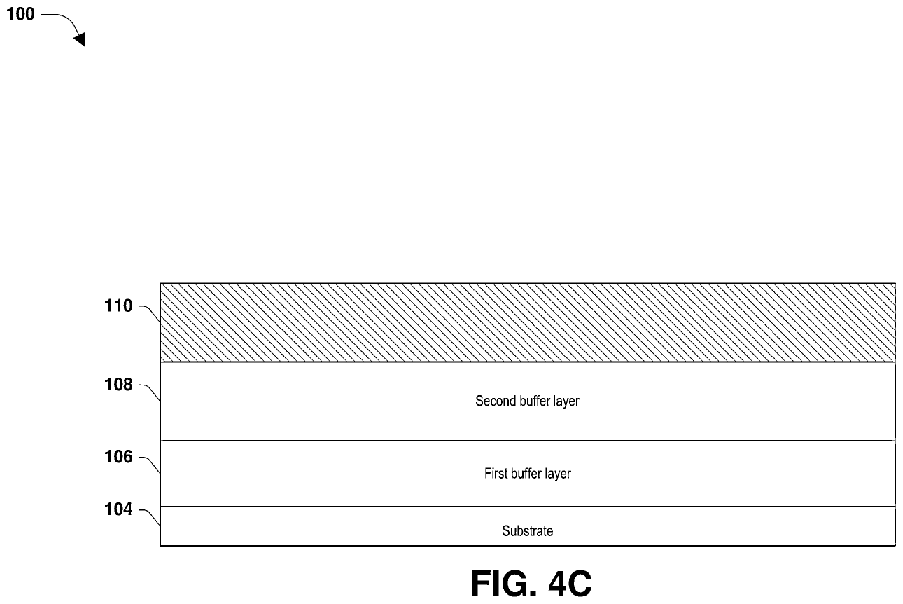

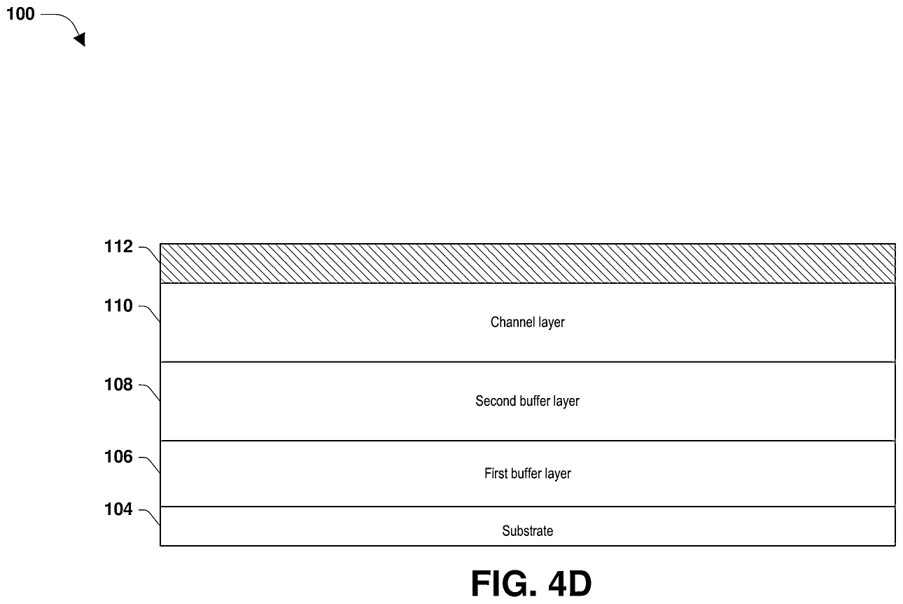

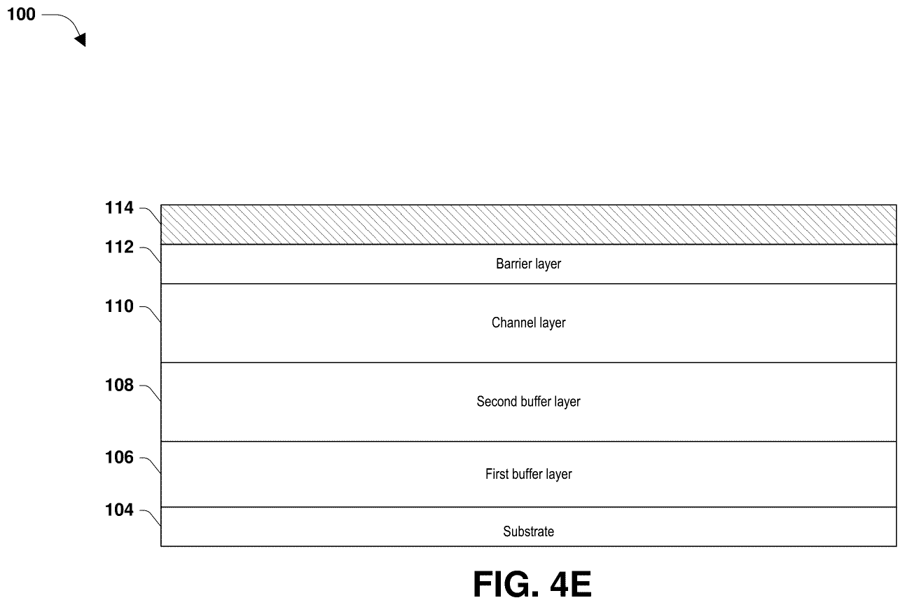

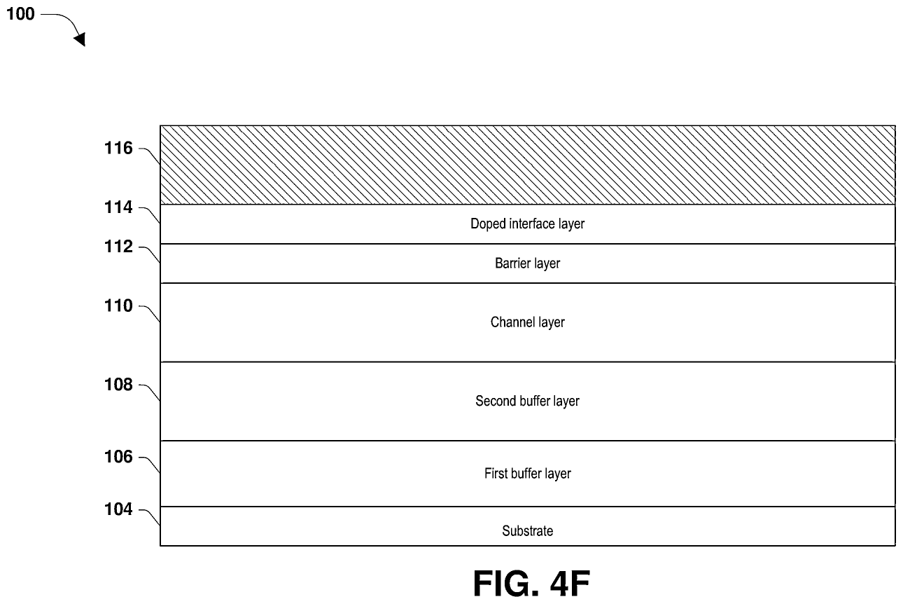

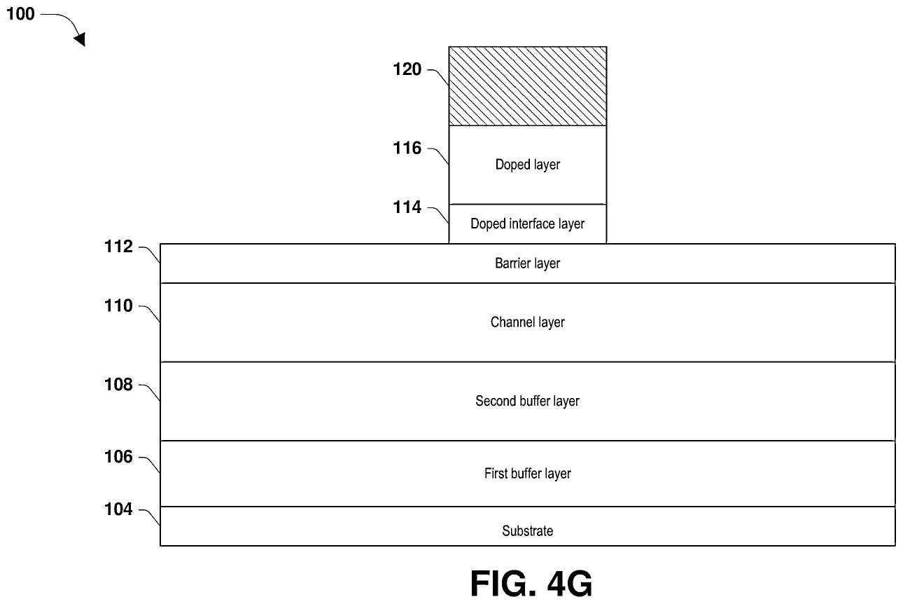

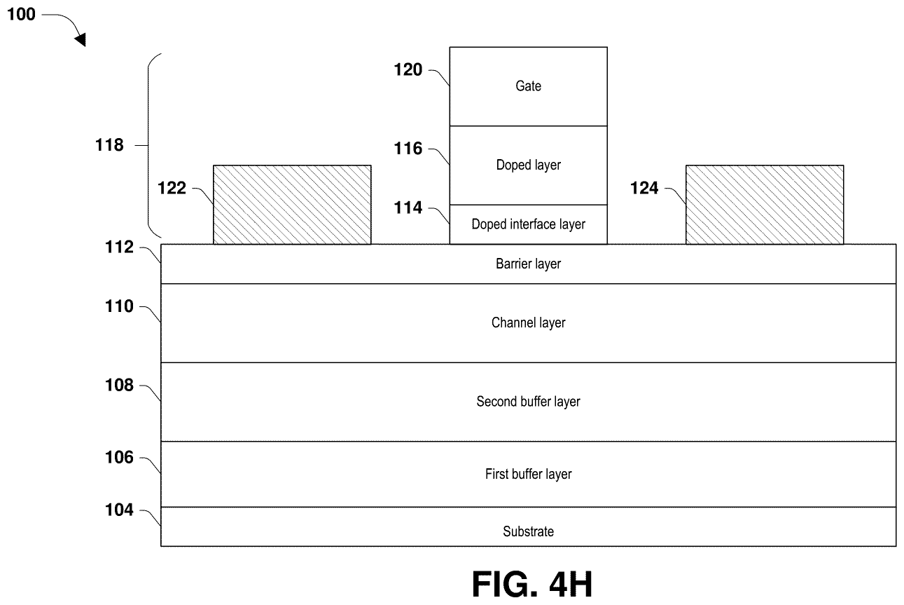

FIGS. 4A-4H illustrate the semiconductor structure 102 at various stages of fabrication, according to some embodiments. Referring to FIG. 4A, the first buffer layer 106 is provided over the substrate 104. The substrate 104 includes a silicon substrate, a silicon carbide (SiC) substrate, or a sapphire substrate. The substrate 104 comprises at least one of an epitaxial layer, a silicon-on-insulator (SOI) structure, a wafer, or a die formed from a wafer. For example, the epitaxial layer may comprise a deposition of an overlayer on a crystalline substrate, where the overlayer is in registry with the substrate 104. In some embodiments, the epitaxial layer may comprise a type of crystal growth or material deposition in which new crystalline layers are formed with one or more well-defined orientations with respect to a crystalline seed layer of the substrate 104. In some embodiments, the substrate 104 comprises at least one of monocrystalline silicon, crystalline silicon with a <100> crystallographic orientation, crystalline silicon with a <110> crystallographic orientation, crystalline silicon with a <111> crystallographic orientation or other suitable material.

In some embodiments, a second substrate (not shown) is bonded with the substrate 104, such as by at least one of one or more bonding layers, an adhesive, a bonding process, or other suitable techniques. In some embodiments where the second substrate is bonded with the substrate 104 using the one or more bonding layers, the one or more bonding layers are between the second substrate and the substrate 104. The second substrate at least one of overlies the substrate, is in direct contact with the substrate 104, or is in indirect contact with the substrate 104. In some embodiments, one or more components of the semiconductor structure 102 are formed through an inversion operation. An inversion operation may be performed such that the semiconductor structure 102 lies beneath at least one of an interconnect structure or the second substrate during formation of one or more components, such as the transistor structure 118, illustrated in FIG. 1. For example, during formation of the interconnect structure, a top surface of the substrate 104 corresponds to a back side the substrate 104, and a bottom surface of the substrate 104 corresponds to a front side of the substrate 104. In some embodiments, a portion of the substrate 104 on the top surface of the substrate 104 is removed, such as after the inversion operation, to reduce a thickness of the substrate 104.

The first buffer layer 106 is formed on the substrate 104. In some embodiments, the first buffer layer 106 acts as a buffer and/or a transition layer for the subsequently formed overlying layers. The first buffer layer 106 may be epitaxially grown using metal-organic chemical vapor deposition (MOCVD). The first buffer layer 106 may function as an interface to reduce lattice mismatch between substrate 104 and the subsequently formed III-V compound layers. In some embodiments, the first buffer layer 106 includes an aluminum nitride (AlN) layer and/or an AlGaN layer having a thickness in a range between about 10 nm to about 300 nm. The first buffer layer 106 may include a single layer or a plurality of layers, as set forth in greater detail herein.

As illustrated in FIG. 4B, the second buffer layer 108 is formed on the first buffer layer 106. The second buffer layer 108 may be a compound made from the III-V groups in the periodic table of elements, as set forth in greater detail herein. In some embodiments, the second buffer layer 108 includes a c-Gan layer. In some embodiments, the second buffer layer 108 may be epitaxially grown by using, for example, MOCVD, during which a gallium-containing precursor and a nitrogen-containing precursor are used, as set forth in greater detail herein. In some embodiments, the second buffer layer 108 is undoped. Alternatively, the second buffer layer 108 is unintentionally doped or may be, for example, lightly doped with p-type dopants due to a precursor used to form other layers of the semiconductor structure 102. In some embodiments, the second buffer layer 108 has a thickness in a range from about 0.5 μm to about 10 μm.

As illustrated in FIG. 4C, the channel layer 110 is formed on the second buffer layer 108. The channel layer 110 is a compound made from the III-V groups in the periodic table of elements, as set forth in greater detail herein. In some embodiments, the channel layer 110 includes u-GaN, as set forth herein. In some embodiments, the channel layer 110 is undoped. In some embodiments, the channel layer 110 is epitaxially grown on the second buffer layer 108 by MOCVD using a gallium-containing precursor, and/or a nitrogen-containing precursor, as set forth herein.

As illustrated in FIG. 4D, the barrier layer 112 is formed on the channel layer 110. The barrier layer 112 is a compound made from the III-V groups in the periodic table of elements, as set forth in greater detail herein. In some embodiments, the barrier layer 112 includes AlGaN, as set forth herein. In some embodiments, the barrier layer 112 is undoped. In some embodiments, the barrier layer 112 is epitaxially grown on the channel layer 110 by MOCVD using a gallium-containing precursor, and/or a nitrogen-containing precursor, as set forth herein.

As illustrated in FIG. 4E, the doped interface layer 114 is formed on the barrier layer 112. The doped interface layer 114 is a compound made from the III-V groups in the periodic table of elements, as set forth herein. In some embodiments, the doped interface layer 114 includes p-AlGaN, as set forth herein. In some embodiments, the doped interface layer 114 is doped with a p-type dopant. In some embodiments, the doped interface layer 114 is epitaxially grown on the barrier layer 112 by MOCVD using a gallium-containing precursor, and/or a nitrogen-containing precursor, as set forth herein.

In some embodiments, a source flow of an organoaluminium compound is controlled during deposition of the doped interface layer 114 to control the aluminum concentration to follow the gradient function 306. In some embodiments, a growth temperature of the doped interface layer 114 is controlled during deposition of the doped interface layer 114 to control the aluminum concentration to follow the gradient function 306. In some embodiments, a growth pressure of the doped interface layer 114 is controlled during deposition of the doped interface layer 114 to control the aluminum concentration to follow the gradient function 306. In some embodiments, a III-V ratio of a III-V compound in the doped interface layer 114 is controlled during deposition of the doped interface layer 114 to control the aluminum concentration to follow the gradient function 306. In some embodiments, the aluminum concentration of the aluminum of the doped interface layer 114 forms the metal concentration matrix 308 as an aluminum concentration matrix that extends into a top portion of the barrier layer 112 and a bottom portion of the doped layer 116.

As illustrated in FIG. 4F, the doped layer 116 is formed on the doped interface layer 114. The doped layer 116 is a compound made from the III-V groups in the periodic table of elements, as set forth herein. In some embodiments, the doped layer 116 includes p-GaN, as set forth herein. In some embodiments, the doped layer 116 is doped with a p-type dopant. In some embodiments, the doped layer 116 is epitaxially grown on the doped interface layer 114 by MOCVD using a gallium-containing precursor, and/or a nitrogen-containing precursor, as set forth herein.

As illustrated in FIG. 4G, the gate electrode 120 is formed on the doped layer 116. In some embodiments, the doped layer 116 and the doped interface layer 114 are patterned, such as by etching, before the gate electrode 120 is formed. Some, none, or all of the doped layer 116 is patterned when the doped interface layer 114 is patterned. In some embodiments, a layer of gate electrode material is formed over the doped layer 116, either before or after the doped layer 116 is patterned, and is patterned to form the gate electrode. Some, none, or all of the layer of gate electrode material is patterned when the doped layer 116 and/or the doped interface layer 114 are patterned. In some embodiments, the layer of gate electrode material and/or the gate electrode 120 is formed using sputtering, atomic layer deposition (ALD), physical vapor deposition (PVD), or another type of metal deposition. The gate electrode 120 includes a metal, such as aluminum, copper, a metal alloy, and/or a combination thereof. In some embodiments, the gate electrode 120 includes at least one of Au, Al, Ti, Ni, Au, or Cu. Other structures and/or configurations of the gate electrode 120 are within the scope of the present disclosure.

As illustrated in FIG. 4H, the source electrode 122 and the drain electrode 124 are formed on the barrier layer 112. In some embodiments, the source electrode 122 and the drain electrode 124 are patterned electrodes formed in a metal layer on the barrier layer 112. In some embodiments, the metal layer and/or other components are formed using sputtering, atomic layer deposition (ALD), physical vapor deposition (PVD), or another type of metal deposition. The source electrode 122 and the drain electrode 124 include a metal, such as aluminum, copper, a metal alloy, and/or a combination thereof. In some embodiments, the source electrode 122 and the drain electrode 124 include at least one of Au, Al, Ti, Ni, Au, or Cu. According to some embodiments, the gate electrode 120, the doped layer 116, the doped interface layer 114, the source electrode 122, and the drain electrode 124 form the transistor structure 118. Other structures and/or configurations of the source electrode 122 and the drain electrode 124 are within the scope of the present disclosure.

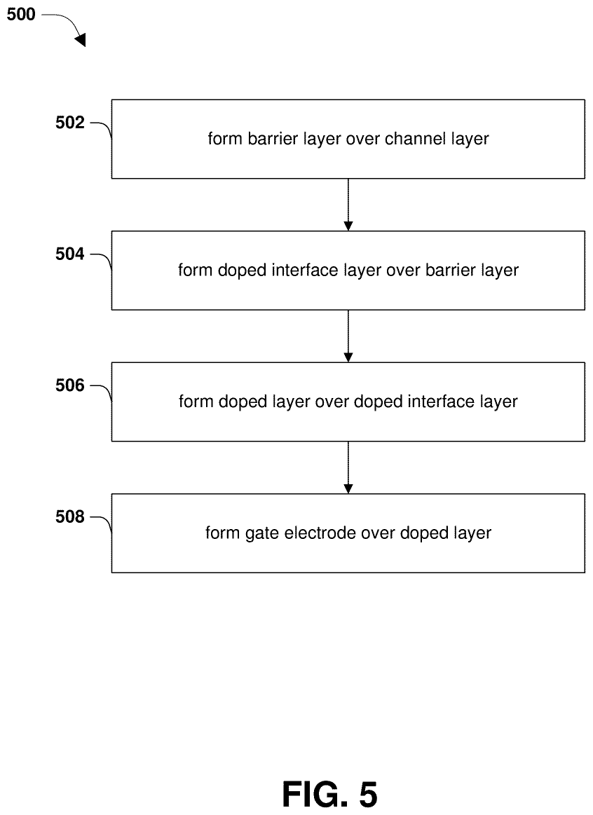

FIG. 5 illustrates a method 500 of making a semiconductor structure, according to some embodiments. Some of the operations described can be replaced and/or eliminated for different embodiments.

At 502, a barrier layer is formed, such as deposited, over a channel layer. For example, in FIG. 1, the barrier layer 112 is deposited over the channel layer 110.

At 504, a doped interface layer is formed, such as deposited, over the barrier layer. For example, in FIG. 1, the doped interface layer 114 is deposited over the barrier layer 112. The doped interface layer 114 includes a dopant and aluminum. An aluminum concentration of the aluminum is controlled to follow a gradient function from a highest aluminum concentration to a lowest aluminum concentration.

At 506, a doped layer is formed, such as deposited, over the doped interface layer. For example, in FIG. 1, the doped layer 116 is deposited over the doped interface layer 114.

At 508, a gate electrode is formed, such as deposited, over the doped layer. For example, in FIG. 1, the gate electrode 120 is formed over the doped layer 116.

Other and/or additional operations of making a semiconductor structure are within the scope of the present disclosure.

In some embodiments, a semiconductor structure is provided. The semiconductor structure includes a barrier layer over a channel layer, and a doped layer over the barrier layer. A gate electrode is over the doped layer and a doped interface layer is formed between the barrier layer and the doped layer. The doped interface layer includes a dopant and a metal. The metal has a metal concentration that follows a gradient function from a highest metal concentration to a lowest metal concentration.

In some embodiments, a high electron mobility transistor is provided. The high electron mobility transistor includes a barrier layer over a channel layer and a doped layer over the barrier layer. The doped layer has a doped potential energy for containing a two-dimensional electron hole gas (2DHG). The high electron mobility transistor includes a doped interface layer formed between the barrier layer and the doped layer. The doped interface layer includes a metal having a metal concentration to match a metal concentration of the barrier layer and a metal concentration of the doped layer. The doped interface layer has an interface potential energy for confining the 2DHG in the doped layer. The high electron mobility transistor includes a gate electrode, over the doped layer, configured for controlling a flow of input current through the 2DHG. The high electron mobility transistor includes a source electrode configured for supplying an input current to the 2DHG and a drain electrode configured for supplying an output current. The input current flows from the source electrode, through the 2DHG, to the drain electrode to produce the output current.

In some embodiments, a method for manufacturing a semiconductor structure is provided. The method includes depositing a barrier layer over a channel layer and depositing, over the barrier layer, a doped interface layer. The doped interface layer comprises a dopant and aluminum. An aluminum concentration of the aluminum is controlled to follow a gradient function from a highest aluminum concentration to a lowest aluminum concentration. The method includes depositing a doped layer over the doped interface layer and forming a gate electrode over the doped layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as CVD, for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor structure, comprising:
a barrier layer over a channel layer;
a doped layer over the barrier layer;
a gate electrode over the doped layer; and
a doped interface layer, formed between the barrier layer and the doped layer, comprising a dopant and a metal having a metal concentration that follows a gradient function from a highest metal concentration to a lowest metal concentration.

2. The semiconductor structure of claim 1, wherein the metal of the doped interface layer comprises aluminum and the metal concentration of the doped interface layer comprises an aluminum concentration.

3. The semiconductor structure of claim 1, wherein the barrier layer comprises the metal having a barrier metal concentration and the gradient function is a ratio of the metal concentration to the barrier metal concentration.

4. The semiconductor structure of claim 3, wherein:
the metal concentration of the doped interface layer is between about 0 and 5 percent of atoms of the doped interface layer; and
the barrier metal concentration of the barrier layer is between about 10 and 30 percent of atoms of the barrier layer.

5. The semiconductor structure of claim 3, wherein the metal of the doped interface layer is formed as a metal concentration matrix that extends into a top portion of the barrier layer and a bottom portion of the doped layer and at least some of the metal concentration matrix has the ratio of the metal concentration to the barrier metal concentration.

6. The semiconductor structure of claim 5, wherein at least one of:
a first portion of the metal concentration matrix extends into the top portion of the barrier layer and has the ratio of between 0.8 and 1;
a second portion of the metal concentration matrix is above the first portion and has the ratio of between 0.5 and 0.8;
a third portion of the metal concentration matrix is above the second portion and has the ratio of between 0.2 and 0.5; or
a fourth portion of the metal concentration matrix is above the third portion, extends into the bottom portion of the doped layer, and has the ratio of between 0.0 and 0.1.

7. The semiconductor structure of claim 1, wherein:
the doped layer is doped with a p-type dopant;
the doped interface layer is doped with the p-type dopant; and
the barrier layer is not doped with the p-type dopant.

8. The semiconductor structure of claim 1, wherein:
the channel layer comprises a first III-V compound;
the barrier layer comprises a second III-V compound;
the doped interface layer comprises a third III-V compound and a dopant; and
the doped layer comprises a fourth III-V compound and the dopant.

9. The semiconductor structure of claim 1, wherein:
the channel layer comprises un-doped gallium nitride (GaN);
the barrier layer comprises aluminum gallium nitride (AlGaN);
the doped interface layer comprises p-type AlGaN and a dopant; and
the doped layer comprises p-type GaN and the dopant,
wherein the gradient function is a ratio of aluminum in the AlGaN of the doped interface layer to aluminum in the AlGaN of the barrier layer.

10. The semiconductor structure of claim 1, wherein:
the doped layer has a doped potential energy for containing a two-dimensional electron hole gas (2DHG); and
the doped interface layer has an interface potential energy for confining the 2DHG in the doped layer.

11. The semiconductor structure of claim 10, comprising:
a source electrode configured for supplying an input current to the 2DHG; and
a drain electrode configured for supplying an output current, wherein the input current flows from the source electrode, through the 2DHG, to the drain electrode to produce the output current, wherein the gate electrode is configured for controlling the flow of the input current through the 2DHG.

12. The semiconductor structure of claim 1, wherein the gradient function of the metal concentration is linear from a top surface of the barrier layer to a bottom surface of the doped layer.

13. The semiconductor structure of claim 1, wherein the gradient function of the metal concentration is curvilinear from a top surface of the barrier layer to a bottom surface of the doped layer such that a middle portion of the doped interface layer has a middle portion metal concentration that is at least one of greater than or less than half of a sum of a highest metal concentration and a lowest metal concentration.

14. A high electron mobility transistor, comprising:
a barrier layer over a channel layer;
a doped layer, over the barrier layer, having a doped potential energy for containing a two-dimensional electron hole gas (2DHG);
a doped interface layer, formed between the barrier layer and the doped layer, comprising a metal having a metal concentration to match a metal concentration of the barrier layer and a metal concentration of the doped layer, wherein the doped interface layer has an interface potential energy for confining the 2DHG in the doped layer;
a gate electrode, over the doped layer, configured for controlling a flow of input current through the 2DHG;
a source electrode configured for supplying an input current to the 2DHG; and
a drain electrode configured for supplying an output current, wherein the input current flows from the source electrode, through the 2DHG, to the drain electrode to produce the output current.

15. A method for manufacturing a semiconductor structure, comprising:
depositing a barrier layer over a channel layer;
depositing, over the barrier layer, a doped interface layer comprising a dopant and aluminum, wherein an aluminum concentration of the aluminum is controlled to follow a gradient function from a highest aluminum concentration to a lowest aluminum concentration;
depositing a doped layer over the doped interface layer; and
forming a gate electrode over the doped layer.

16. The method of claim 15, comprising:
controlling a source flow of an organoaluminium compound during deposition of the doped interface layer to control the aluminum concentration to follow the gradient function.

17. The method of claim 15, comprising:
controlling a growth temperature of the doped interface layer during deposition of the doped interface layer to control the aluminum concentration to follow the gradient function.

18. The method of claim 15, comprising:
controlling a growth pressure of the doped interface layer during deposition of the doped interface layer to control the aluminum concentration to follow the gradient function.

19. The method of claim 15, comprising:
controlling a III-V ratio of a III-V compound in the doped interface layer during deposition of the doped interface layer to control the aluminum concentration to follow the gradient function.

20. The method of claim 15, wherein the aluminum concentration of the aluminum forms an aluminum concentration matrix that extends into a top portion of the barrier layer and a bottom portion of the doped layer.
